(19) United States
(12) Patent Application Publication
(10) Pub. No.: US 2025/0015566 A1
(43) Pub. Date: Jan. 9, 2025

(54) VERTICAL-CAVITY SURFACE-EMITTING LASER ARRAY AND METHOD FOR FORMING THE SAME

(71) Applicant: WIN SEMICONDUCTORS CORP., TAOYUAN CITY (TW)

(72) Inventors: Kai-Jie CHANG, TAOYUAN CITY (TW); Wan-Ting CHIEN, TAOYUAN CITY (TW); Yu-Chun CHEN, TAOYUAN CITY (TW); Chia-Ta CHANG, TAOYUAN CITY (TW); Jeng-Lin WU, TAOYUAN CITY (TW)

(21) Appl. No.: 18/347,663

(22) Filed: Jul. 6, 2023

(51) Int. Cl. H01S 5/42; H01S 5/042; H01S 5/183

(52) U.S. Cl. CPC H01S 5/423; H01S 5/0421; H01S 5/18311

(57) ABSTRACT

A vertical-cavity surface-emitting laser array includes a substrate. The VCSEL array also includes an active layer formed between a lower mirror and an upper mirror. The VCSEL array also includes a contact layer formed between the active layer and the substrate. The VCSEL array also includes an isolation trench between the first VCSEL and the second VCSEL of the VCSEL array. The isolation trench extending through the contact layer is filled with a filler.

### BACKGROUND OF THE INVENTION

### Field of the Invention

The disclosure relates to a vertical-cavity surface-emitting laser (VCSEL) array, and more particularly to a two-dimensional VCSEL array and a method for forming the same.

### Description of the Related Art

A VCSEL is a semiconductor laser diode whose laser beam is emitted in the direction perpendicularly to its surface. VCSEL may be tested during production. VCSEL is widely adopted for use in various applications, such as LIDAR, optical fiber communications and biometrics.

For a two-dimensional VCSEL array, both of the anode and the cathode may be formed on the top surface of the substrate. A trench may be formed between the VCSELs as isolation. However, it may raise challenges for subsequent processes. For example, the needed photoresist layer for patterning a subsequent layer may be too thick and result in reliability issue. In addition, since the product may be operated with a high voltage, there may be a leakage current at the trench.

Although existing VCSEL array have generally been adequate for their intended purposes, they have not been entirely satisfactory in all respects, and need to be improved.

### BRIEF SUMMARY OF THE INVENTION

An embodiment of the present invention provides a vertical-cavity surface-emitting laser (VCSEL) array including a substrate, an active layer, a contact layer, and an isolation trench. The active layer is formed between a lower mirror and an upper mirror. The contact layer is formed between the active layer and the substrate. The isolation trench is formed between the first VCSEL and the second VCSEL of the VCSEL array. The isolation trench extending through the contact layer is filled with a filler.

An embodiment of the present invention provides a VCSEL array including a lower mirror with an isolation layer formed over a substrate. An active layer is formed over the lower mirror. An upper mirror is formed over the active layer. A contact layer is formed over the isolation layer. A first electrode is formed over the upper mirror. A second electrode formed over the contact layer. An isolation trench surrounds a VCSEL of the VCSEL array. A dielectric layer is formed over the second electrode. The isolation trench is filled with a different filler than the material of the dielectric layer.

In addition, an embodiment of the present invention provides a method for forming a VCSEL array. The method includes forming a lower mirror and a contact layer over a substrate. The method also includes forming an active layer over the lower mirror. The method also includes forming an upper mirror over the active layer. The method also includes patterning the upper mirror, the active layer, and the lower mirror to form a mesa over the contact layer. The method also includes forming a first electrode over the mesa. The method also includes forming a second electrode over the contact layer. The method also includes forming a trench in the contact layer and the lower mirror. The method also includes filling the trench with a filler.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1E are cross-sectional representations of various stages of forming a VCSEL array in accordance with some embodiments.

FIG. 2 is a top view of a VCSEL array in accordance with some embodiments.

FIG. 3 is an enlarged cross-sectional representation of a VCSEL array in accordance with some embodiments.

FIG. 4 is an enlarged cross-sectional representation of a modified VCSEL array in accordance with some embodiments.

FIG. 5 is a cross-sectional representation of a modified VCSEL array in accordance with some embodiments.

FIG. 6 is a cross-sectional representation of a modified VCSEL array in accordance with some embodiments.

FIG. 7 is a cross-sectional representation of a modified VCSEL array in accordance with some embodiments.

FIG. 8 is a cross-sectional representation of a modified VCSEL array in accordance with some embodiments.

FIG. 9 is a cross-sectional representation of a modified VCSEL array in accordance with some embodiments.

FIG. 10 is a cross-sectional representation of a modified VCSEL array in accordance with some embodiments.

FIG. 11 is a cross-sectional representation of a modified VCSEL array in accordance with some embodiments.

### DETAILED DESCRIPTION OF THE INVENTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Herein, the terms “around,” “about,” “substantial” usually mean within 20% of a given value or range, preferably within 10%, and better within 5%, or 3%, or 2%, or 1%, or 0.5%. It should be noted that the quantity herein is a substantial quantity, which means that the meaning of “around,” “about,” “substantial” are still implied even without specific mention of the terms “around,” “about,” “substantial.”

Although some embodiments are discussed with operations performed in a particular order, these operations may be performed in another logical order. In different embodiments, additional operations can be provided before, during, and/or after the stages described the present disclosure. Some of the stages that are described can be replaced or eliminated for different embodiments. Additional features can be added to the semiconductor structure in the present disclosure. Some of the features described below can be replaced or eliminated for different embodiments.

The embodiments of the present disclosure provide a two-dimensional vertical cavity surface emitting laser (VCSEL) array. The trench between the VCSELs is filled with a filler. The height difference of the VCSEL array is reduced, and thinner photoresist layer may be used in the etching process (e.g., an etching process for forming a via). In addition, the leakage current through the trench may be prevented.

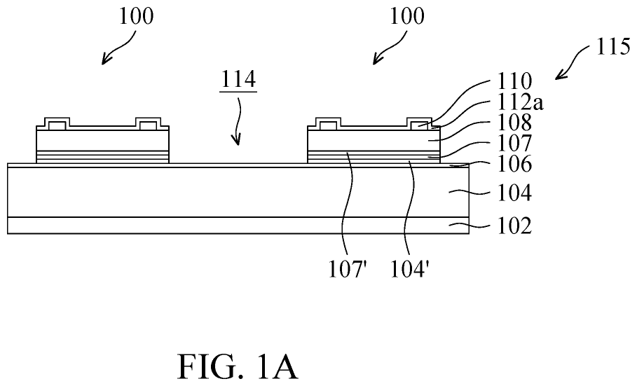

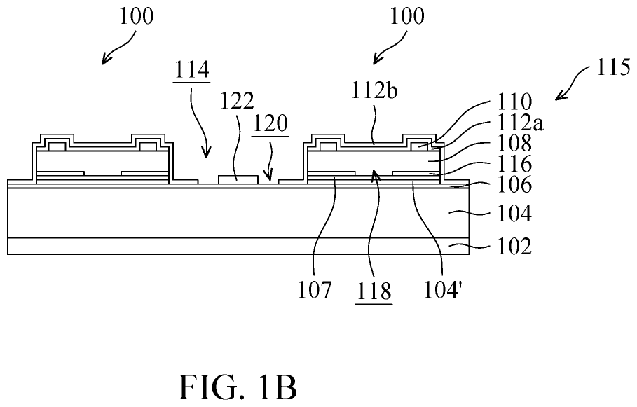

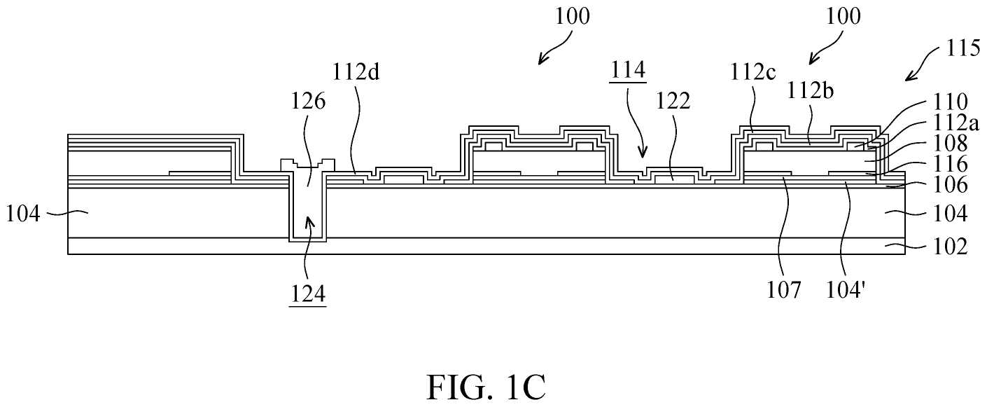

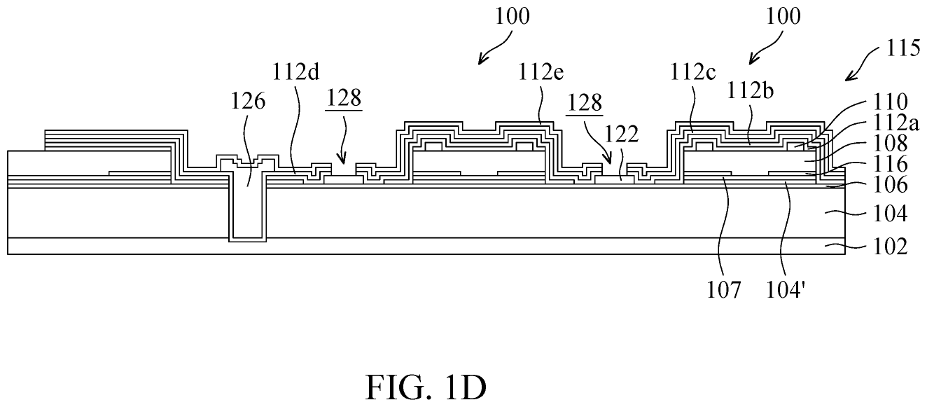

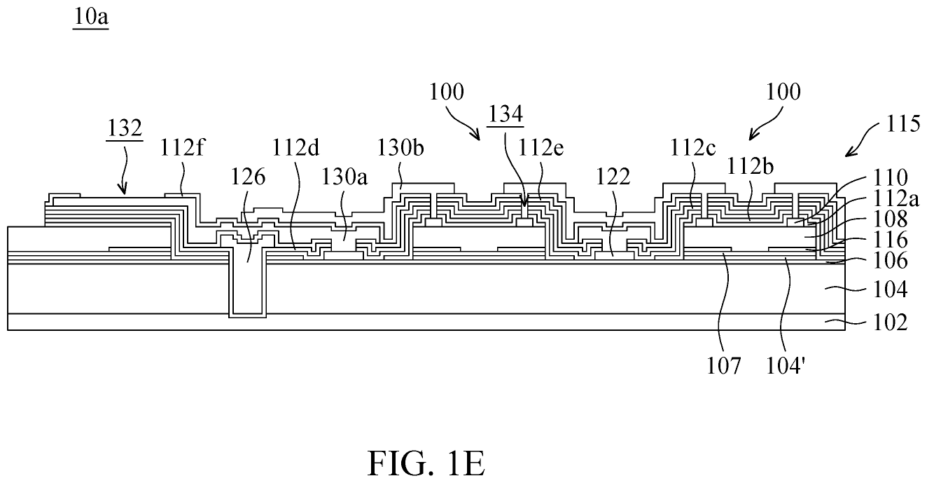

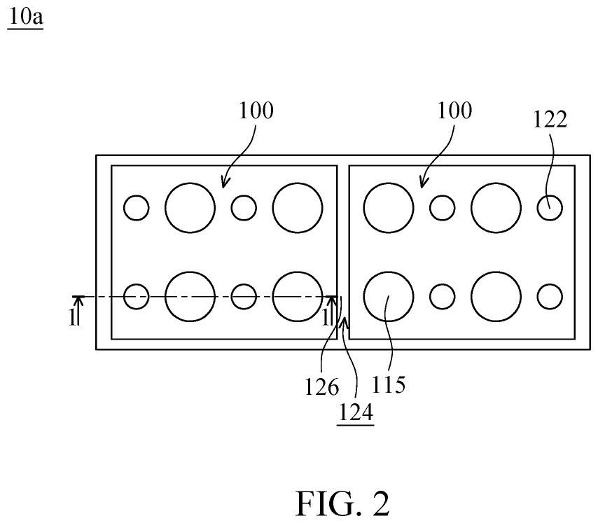

FIGS. 1A-1E are cross-sectional representations of various stages of forming a VCSEL array 10a in accordance with some embodiments. FIG. 2 is a top view of a VCSEL array 10a in accordance with some embodiments. FIGS. 1A-1E show cross-sectional representations taken along line 1-1 in FIG. 2.

A substrate 102 is provided, as shown in FIG. 1A in accordance with some embodiments. The substrate 102 may be a semiconductor substrate. The substrate 102 may include III-V semiconductors, such as GaAs, GaN, AlGaN, AlN, AlGaAs, InP, InAlAs, InGaAs, or a combination thereof. In some embodiments, the substrate 102 includes GaAs. In some embodiments, the substrate 102 is n-type doped or p-type doped. In some embodiments, the substrate 102 is a semi-insulating substrate.

Next, a first mirror 104 is formed over the substrate 102, as shown in FIG. 1A in accordance with some embodiments. The first mirror 104 may include an n-type mirror, a p-type mirror, an un-doped mirror, or a combination thereof. In some embodiments, the conductive type of the upper portion of the first mirror 104 is opposite to that of the lower portion of the first mirror 104.

In some embodiments, the first mirror 104 includes first semiconductor layers and second semiconductor layers. The first mirror 104 includes alternately stacked first semiconductor layers and second semiconductor layers over the substrate 102. The first semiconductor layer and the second semiconductor layer are used in pairs. The first semiconductor layers and the second semiconductor layers may include III-V semiconductors, such as AlGaAs, GaAs, AlAs, GaN, AlGaN, AlN, InP, InAlAs, InGaAs, or a combination thereof. The first semiconductor layers and the second semiconductor layers may be made of different materials with different refractive indexes. The first semiconductor layers and the second semiconductor layers may have a first conductivity type. In some embodiments, the first conductivity type is n-type. The first mirror 104 may be referred to as a distributed Bragg reflector (DBR) of a first conductivity type. The thickness of each layer of the first semiconductor layers and the second semiconductor layers may depend on the center wavelength of laser light generated in the VCSELs 100 in the VCSEL array 10a. The first semiconductor layers and the second semiconductor layers may be formed by a low-pressure chemical vapor deposition (LPCVD) process, an epitaxial growth process, another applicable method, or a combination thereof. The epitaxial growth process may include molecular beam epitaxy (MBE), metal organic chemical vapor deposition (MOCVD), or vapor phase epitaxy (VPE). The total number of such pairs of the first semiconductor layers and the second semiconductor layers are not limited, depending on the demand of design.

A contact layer 106 is formed on the first mirror 104, as shown in FIG. 1A in accordance with some embodiments. The contact layer 106 may be an etch stop layer for forming a mesa in the subsequently etching process. The contact layer 106 may be made of a semiconductor layer electrically connected to subsequently formed electrode. The contact layer 106 may include III-V semiconductors, such as AlGaAs, GaAs, AlAs, GaN, AlGaN, AlN, InP, InAlAs, InGaAs, other applicable materials, or a combination thereof. The contact layer 106 may be formed by a low-pressure chemical vapor deposition (LPCVD) process, an epitaxial growth process, other applicable processes, or a combination thereof. The epitaxial growth process may include molecular beam epitaxy, metal organic chemical vapor deposition, or vapor phase epitaxy.

Next, an intermediate mirror 104′ is formed over the contact layer 106, in accordance with some embodiments. Processes and materials used to form the intermediate mirror 104′ may be similar to, or the same as, those used to form the first mirror 104 described previously and are not repeated herein for brevity.

Afterwards, an active layer 107 is formed over the first mirror 104, as shown in FIG. 1A in accordance with some embodiments. The active layer 107 may be a multi-layer structure.

The active layer 107 may include a number of quantum wells and quantum well barriers. The quantum wells and the quantum well barriers may include III-V semiconductors such as AlGaAs, GaAs, AlAs, GaN, AlGaN, AlN, InP, InAlAs, InGaAs, or a combination thereof. The quantum wells and the quantum well barriers may be made of different materials, and the quantum well barriers may have a greater energy band gap than the quantum wells. The active layer 107 may generate the optical power for the VCSEL 10a.

In some embodiments, the active layer 107 includes multiple active junction layers with a tunneling junction layer sandwiched between active junction layers. In some embodiments, the active junction layer of the active layer 107 includes an un-doped semiconductor layer sandwiched between a p-type doped semiconductor layer and an n-type doped semiconductor layer. In some embodiments, the tunneling junction layer includes n-type doped semiconductor layer and p-type doped semiconductor layer. In some embodiments, the dopant concentration of the tunneling junction layer is greater than the dopant concentration of the p-type doped semiconductor layer and the n-type doped semiconductor layer of the active junction layer.

The active layer 107, including the quantum wells and the quantum well barriers, may be formed by a low-pressure chemical vapor deposition (LPCVD) process, an epitaxial growth process, another applicable method, or a combination thereof. The epitaxial growth process may include molecular beam epitaxy, metal organic chemical vapor deposition, or vapor phase epitaxy. The active layer 107 may separate the underlying first mirror 104 and the subsequently formed second mirror.

Next, a semiconductor layer 107′ is formed over the active layer 107. The semiconductor layer 107′ may include III-V semiconductors, such as GaAs, AlGaAs, AlAs, GaN, AlGaN, AlN, InP, InAlAs, InGaAs, or a combination thereof. In some embodiments, the semiconductor layer 107′ includes AlGaAs. The semiconductor layer 107′ may be formed by a low-pressure chemical vapor deposition (LPCVD) process, an epitaxial growth process, another applicable method, or a combination thereof. The epitaxial growth process may include molecular beam epitaxy, metal organic chemical vapor deposition, or vapor phase epitaxy.

Next, a second mirror 108 is formed over the semiconductor layer 107′, as shown in FIG. 1A in accordance with some embodiments. The second mirror 108 may include an n-type mirror, a p-type mirror, an un-doped mirror, or a combination thereof. In some embodiments, the conductive type of the upper portion of the second mirror 108 is opposite to that of the lower portion of the second mirror 108.

The second mirror 108 may include third semiconductor layers and fourth semiconductor layers alternating stacked over the semiconductor layer 107′. The third semiconductor layers and the fourth semiconductor layers may include III-V semiconductors, such as AlGaAs, GaAs, AlAs, GaN, AlGaN, AlN, InP, InAlAs, InGaAs, or a combination thereof. The third semiconductor layers and the fourth semiconductor layers may be made of different materials with different refractive indexes. In some embodiments, the third semiconductor layers and the fourth semiconductor layers have a second conductivity type. In some embodiments, the second conductivity type is p-type. The second mirror 108 may be referred to as a distributed Bragg reflector (DBR) of a second conductivity type. Processes used to form the second mirror 108 may be similar to, or the same as, those used to form the first mirror 104 described previously and are not repeated herein for brevity. The number of the third semiconductor layers and the fourth semiconductor layers are not limited herein, depending on the demand of design.

Next, a first electrode material is formed on the second mirror 108, as shown in FIG. 1A in accordance with some embodiments. In some embodiments, an ohmic contact is formed between the first electrode material and the second mirror 108. The first electrode material may include Pt, Ti, Au, Al, Pd, Cu, W, other suitable metal, its alloy, or a combination thereof. A first electrode material may be formed on the second mirror 108 by e-beam evaporation, resistive heating evaporation, electroplating, sputtering, physical vapor deposition (PVD), chemical vapor deposition (CVD), atomic layer deposition (ALD), another suitable method, or a combination thereof. In some embodiments, the first electrode material is formed by e-beam evaporation. The first electrode material is patterned to form a first electrode 110 over the second mirror 108, as shown in FIG. 1A in accordance with some embodiments.

Next, a first insulating layer 112a is conformally formed over the first electrode 110 and the second mirror 108, as shown in FIG. 1A in accordance with some embodiments. The first insulating layer 112a may be made of silicon nitride, aluminum oxide, other suitable insulating material, or a combination thereof. In some embodiments, the first insulating layer 112a includes silicon nitride. The first insulating layer 112a may be formed by a deposition process. The deposition process may include a CVD process (such as LPCVD, PECVD, SACVD, or FCVD), an ALD process, another applicable method, or a combination thereof.

Next, a trench 114 is formed through the first insulating layer 112a, the second mirror 108, the semiconductor layer 107′, the active layer 107, the intermediate mirror 104″, and stopped on the contact layer 106, as shown in FIG. 1A in accordance with some embodiments. In some embodiments, a mesa 115 is formed over the contact layer 106, and the first electrode 110 is formed over the mesa 115. The trench 114 may be formed by a patterning process. The patterning process may include a photolithography process and an etching process. Examples of photolithography processes include photoresist coating, soft baking, mask aligning, exposure, post-exposure baking, developing the photoresist, rinsing and drying. The etching process may be a dry etching process or a wet etching process. In some embodiments, the etching process is a reactive-ion etching (RIE) using inductively coupled plasma (ICP) as etchers.

Next, a portion of the semiconductor layer 107′ is oxidized to form an oxide layer 116, as shown in FIG. 1B in accordance with some embodiments. The semiconductor layer 107′ may contain high Al composition. The Al composition may affect the oxidation rate. The oxide layer 116 may include insulating oxides such as Al₂O₃. In some embodiments, the oxide layer 116 is formed by a furnace oxidation process.

In some embodiments, only a portion of the semiconductor layer 107′ is oxidized. In some embodiments, the un-oxidized portion of the semiconductor layer 107′ may serve as an aperture 118. The aperture 118 may be include III-V semiconductors, such as AlGaAs, GaAs, AlAs, GaN, AlGaN, AlN, InP, InAlAs, InGaAs, or a combination thereof. In some embodiments, the aperture 118 is surrounded by the oxide layer 116. In some embodiments, the second mirror 108 is over the aperture 118 and the oxide layer 116. The aperture 118 may confine a current from the first electrode 110 passing through the underlying active layer 107, the intermediate mirror 104′, the contact layer 106, and the first mirror 104.

Afterwards, a second insulating layer 112b is conformally formed over the first insulating layer 112a and the sidewalls and the bottom surface of the trench 114, as shown in FIG. 1B in accordance with some embodiments. The second insulating layer 112b may cover the top surface and the sidewalls of the mesa 115. The second insulating layer 112b may be made of silicon nitride, aluminum oxide, other suitable insulating material, or a combination thereof. The second insulating layer 112b may be formed by a CVD process (such as LPCVD, PECVD, SACVD, or FCVD), an ALD process, another applicable method, or a combination thereof. In some embodiments, the second insulating layer 112b and the first insulating layer 112a are made of the same material. Therefore, there may be no obvious interface between the first insulating layer 112a and the second insulating layer 112b.

Afterwards, an opening 120 is formed in the second insulating layer 112b covering the contact layer 106, as shown in FIG. 1B in accordance with some embodiments. The contact layer 106 at the bottom of the trench 114 may be exposed from the opening 120. In some embodiments, a portion of the contact layer 106 at the bottom of the trench 114 is covered by the second insulating layer 112b after the opening 120 is formed. The opening 120 may be formed by a patterning process.

Next, a second electrode material is formed on the contact layer 106 in accordance with some embodiments. In some embodiments, an ohmic contact is formed between the second electrode material and the contact layer 106. The second electrode material may include Pd, Ge, Ti, Pt, Au, other suitable metal, its alloy, or a combination thereof. The second electrode material is patterned to form a second electrode 122 in the opening 120 over the contact layer 106. In some embodiments, the second electrode 122 is separated from the second insulating layer 112b.

Afterwards, a third insulating layer 112c is conformally formed over the second insulating layer 112b, the second electrode 122, and the sidewalls and the bottom surface of the trench 114, as shown in FIG. 1C in accordance with some embodiments. The third insulating layer 112c may be formed over the second insulating layer 112b and extended into the trench 114. In some embodiments, the third insulating layer 112c covers the top surface and the sidewalls of the second electrode 122. In some embodiments, the third insulating layer 112c is in direct contact with the contact layer 106 between the second electrode 122 and the mesa 115. The third insulating layer 112c may be made of silicon nitride, aluminum oxide, other suitable insulating material, or a combination thereof. The third insulating layer 112c may be formed by a CVD process (such as LPCVD, PECVD, SACVD, or FCVD), an ALD process, another applicable method, or a combination thereof. In some embodiments, the third insulating layer 112c, the second insulating layer 112b and the first insulating layer 112a are made of the same material. Therefore, there may be no obvious interface between them.

Next, an isolation trench 124 is formed through the third insulating layer 112c, the second insulating layer 112b, the contact layer 106, the first mirror 104, and the substrate 102 as shown in FIG. 1C in accordance with some embodiments. In some embodiments as shown in FIG. 2, the isolation trench 124 is formed between VCSELs 100 of the VCSEL array 10a. The isolation trench 124 may be formed by a patterning process. In some embodiments, the VCSEL array 10a includes multiple VCSELs 100, and adjacent VCSELs 100 of the VCSEL array 10a are electrically isolated from each other by the isolation trench 124. In some embodiments, the VCSEL array 10a includes multiple subgroups of VCSELs 100, and adjacent subgroups of the VCSEL array 10a are electrically isolated from each other by the isolation trench 124.

Next, a fourth insulating layer 112d is conformally formed over the third insulating layer 112c, and the sidewalls and the bottom surface of the isolation trench 124, as shown in FIG. 1C in accordance with some embodiments. The fourth insulating layer 112d may be formed over the third insulating layer 112c. In some embodiments, the fourth insulating layer 112d is formed lining the isolation trench 124. The fourth insulating layer 112d may be made of silicon nitride, aluminum oxide, other suitable insulating material, or a combination thereof. The fourth insulating layer 112d may be formed by a CVD process (such as LPCVD, PECVD, SACVD, or FCVD), an ALD process, another applicable method, or a combination thereof. In some embodiments, the fourth insulating layer 112d, the third insulating layer 112c, the second insulating layer 112b, and the first insulating layer 112a are made of the same material. Therefore, there may be no obvious interface between them.

Next, a filler 126 is filled in the isolation trench 124, as shown in FIG. 1C in accordance with some embodiments. The filler 126 may include metal material such as Au, Cu, Ti, Ni, polymer material such as benzocyclobutene (BCB), polybenzoxazoles (PBO), Polyimide (PI), and dielectric material such as SiNₓ, SiO₂, Al₂O₃, HFO₂, a-Si (amorphous Silicon), other suitable materials, or a combination thereof. The filler 126 may be formed by electroplating, e-beam evaporation, resistive heating evaporation, sputtering, physical vapor deposition (PVD), chemical vapor deposition (CVD), atomic layer deposition (ALD), another suitable method, or a combination thereof. In some embodiments, the filler 126 is made of Au formed by electroplating. In some embodiments, the filler 126 made of metal material has good mechanical property (e.g., strength, hardness) and can maintain adequate mechanical property after undergoing subsequent process for manufacturing the VCSEL array (e.g., process with higher temperature such as annealing, deposition process, bumping process, or cutting process). In some embodiments, the filler 126 and the fourth insulating layer 112d are made of different materials. In some embodiments, the filler 126 is electrically isolated from the contact layer 106 by the fourth insulating layer 112d. In some embodiments, the filler 126 is made of metal, the contact layer 106 is made of semiconductor layer, and they are electrically isolated from each other by the insulating layer 112d.

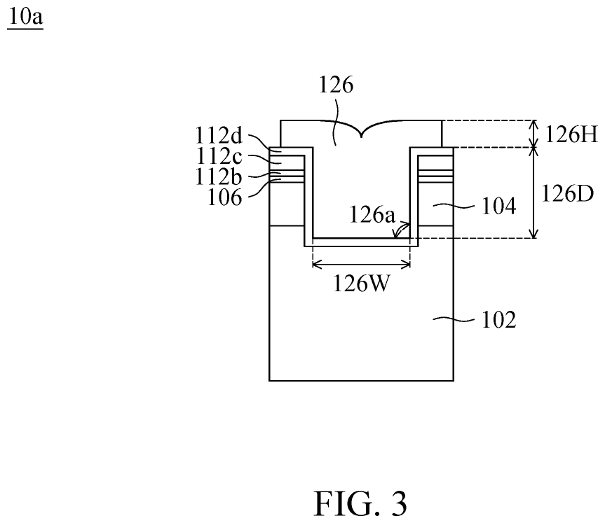

FIG. 3 is an enlarged cross-sectional representation of a VCSEL 100 of the VCSEL array 10a in accordance with some embodiments. In some embodiments, the filler 126 is T-shaped in a cross-sectional view. In some embodiments, the middle of the top surface of the filler 126 is lower than both ends of the top surface of the filler 126. In some embodiments, the top portion of the filler 126 laterally extends out of the isolation trench 124.

In some embodiments, the filler 126 has a bottom width 126W. The bottom width 126W of the filler 126 is in a range of about 1 μm to about 20 μm. In some embodiments, the filler 126 has a depth 126D in the isolation trench 124. The depth 126D of the filler 126 is in a range of about 1 μm to about 10 μm. In some embodiments, the ratio of the depth 126D to the bottom width 126W of the filler 126 is in a range of about 0.5 to about 20. If the ratio of the depth 126D to the bottom width 126W of the filler 126 is too high, the filler coverage may be poor, or the device reliability may be worse. If the ratio of the depth 126D to the bottom width 126W of the filler 126 is too low, the filler coverage may be poor, or the design flexibility may be limited.

In some embodiments, the extending portion of the filler 126 out of the isolation trench 124 has a height 126H. The height 126H of the extending portion of the filler 126 is in a range of about 2 μm to about 10 μm. In some embodiments, the ratio of the height 126H of the extending portion to the depth 126D in the isolation trench 124 is in a range of about 0.2 to about 10. If the ratio of the height 126H of the extending portion to the depth 126D in the isolation trench 124 is too high, the topography for the following process may be too large. If the ratio of the height 126H of the extending portion to the depth 126D in the isolation trench 124 is too low, the filler coverage may be poor, or the he device reliability may be worse.

In some embodiments, the angle 126a between the sidewall and the bottom surface of the filler 126 is in a range of about 85 degree to about 110 degree. If the angle 126a is too great, the device area may be too large. If the angle 126a is too less, it may be difficult to fill the filler material in the isolation trench 124.

Next, a fifth insulating layer 112e is conformally formed over the fourth insulating layer 112d and the filler 126, as shown in FIG. 1D in accordance with some embodiments. The fifth insulating layer 112e may be made of silicon nitride, aluminum oxide, other suitable insulating material, or a combination thereof. The fifth insulating layer 112e may be formed by a CVD process (such as LPCVD, PECVD, SACVD, or FCVD), an ALD process, another applicable method, or a combination thereof. In some embodiments, the fifth insulating layer 112e, the fourth insulating layer 112d, the third insulating layer 112c, the second insulating layer 112b, and the first insulating layer 112a are made of the same material. Therefore, there may be no obvious interface between them.

Afterwards, an opening 128 is formed in the fifth insulating layer 112e, the fourth insulating layer 112d, and the third insulating layer 112c over the second electrode 122, as shown in FIG. 1D in accordance with some embodiments. The second electrode 122 may be exposed from the opening 128. In some embodiments, a portion of the second electrode 122 is covered by the third insulating layer 112c after the opening 128 is formed. The opening 128 may be formed by a patterning process.

Next, a first bonding pad layer 130a is formed in the opening 128 and covering the filler 126, as shown in FIG. 1E in accordance with some embodiments. In some embodiments, the mesa 115 with the first electrode 110 formed over it is exposed from the first bonding pad layer 130a. The first bonding pad layer 130a may be formed by electroplating, e-beam evaporation, resistive heating evaporation, sputtering, physical vapor deposition (PVD), chemical vapor deposition (CVD), atomic layer deposition (ALD), another suitable method, or a combination thereof.

Next, a sixth insulating layer 112f is conformally formed over the first bonding pad layer 130a and the fifth insulating layer 112e, as shown in FIG. 1E in accordance with some embodiments. The sixth insulating layer 112f may be made of silicon nitride, aluminum oxide, other suitable insulating material, or a combination thereof. The sixth insulating layer 112f may be formed by a CVD process (such as LPCVD, PECVD, SACVD, or FCVD), an ALD process, another applicable method, or a combination thereof. In some embodiments, the sixth insulating layer 112f, the fifth insulating layer 112e, the fourth insulating layer 112d, the third insulating layer 112c, the second insulating layer 112b, and the first insulating layer 112a are made of the same material. Therefore, there may be no obvious interface between them.

Afterwards, an opening 132 is formed in the sixth insulating layer 112f over the first bonding pad layer 130a, as shown in FIG. 1E in accordance with some embodiments. The first bonding pad layer 130a may be exposed from the opening 132. The opening 132 may be formed by a patterning process.

Next, an opening 134 is formed in the sixth insulating layer 112f, the fifth insulating layer 112e, the fourth insulating layer 112d, the third insulating layer 112c, the second insulating layer 112b, and the first insulating layer 112a over the first electrode 110, as shown in FIG. 1E in accordance with some embodiments. The first electrode 110 may be exposed from the opening 134. The opening 134 may be formed by a patterning process.

With the filler 126 formed in the isolation trench 124, thinner photoresist layer may be used in the etching process forming the opening 134 and/or opening 132. In some embodiments, since thinner photoresist layer is used in the etching process, the reliability and the yield of the VCSEL array 10a can be improved. For example, the photoresist layer used in the etching process is less than 10 μm (e.g., in a range between 2 μm and 9 μm).

Next, a second bonding pad layer 130b is formed in the opening over the first electrode 110 and covering the sixth insulating layer 112f, as shown in FIG. 1E in accordance with some embodiments. In some embodiments, the second bonding pad layer 130b partially covers the first bonding pad layer 130a, and the first bonding pad layer 130a is exposed from the opening 132. The second bonding pad layer 130b may be formed by electroplating, e-beam evaporation, resistive heating evaporation, sputtering, physical vapor deposition (PVD), chemical vapor deposition (CVD), atomic layer deposition (ALD), another suitable method, or a combination thereof.

In some embodiments, the first electrode 110 and the second electrode 122 are formed on the same side of the substrate 102, and thus the VCSEL array 10a can be bonded to another substrate by a flip-chip process, a wafer bonding process, or a combination thereof. In some embodiments, the VCSEL array 10a is bonded to a driver IC, a sub-mount, a PCB, or a ceramic substrate by a flip-chip or wafer bonding process.

With a filler 126 formed in the isolation trench 124 between the VCSELs 100 of the VCSEL array 10a, thinner photoresist layer may be used in the patterning process (e.g., the patterning process for forming the via hole on the mesa 115), and thus the reliability and/or the yield of the VCSEL array 10a may be improved. In addition, the filler 126 in the isolation trench 124 may reduce the leakage current and thus improve the performance of the VCSEL array 10a.

In some embodiments, the VCSEL array 10a may be applied in a LIDAR system, a 3D sensing system, a data communication system, or a combination thereof.

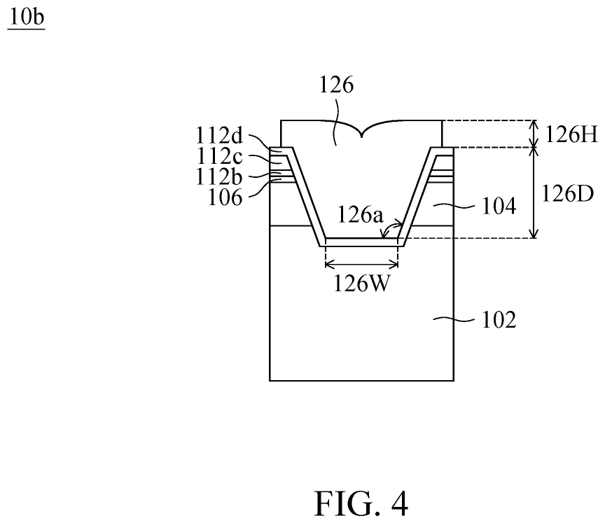

Many variations and/or modifications may be made to the embodiments of the disclosure. FIG. 4 is an enlarged cross-sectional representation of a VCSEL 10b in accordance with some embodiments. Some processes or devices are the same as, or similar to, those described in the embodiments above, and therefore the descriptions of these processes and devices are not repeated herein. The difference from the embodiments described above is that, as shown in FIG. 4 in accordance with some other embodiments, the isolation trench 124 and the filler 126 has a tapered sidewall.

In some embodiments as shown in FIG. 4, the angle 126a between the sidewall and the bottom surface of the filler 126 is in a range of about 110 degree to about 150 degree. The quality of the filler 126 may be better since it may be easier to form the filler 126 in the isolation trench 124.

With a filler 126 formed in the isolation trench 124 between the VCSELs 100 of the VCSEL array 10b, thinner photoresist layer may be used in the patterning process (e.g., the patterning process for forming the via hole on the mesa 115), and thus the reliability and/or the yield of the VCSEL array 10b may be improved. In addition, the filler 126 in the isolation trench 124 may reduce the leakage current and thus improve the performance of the VCSEL array 10b. The isolation trench 124 and the filler 126 may have a tapered sidewall and the quality of the filler 126 may be improved.

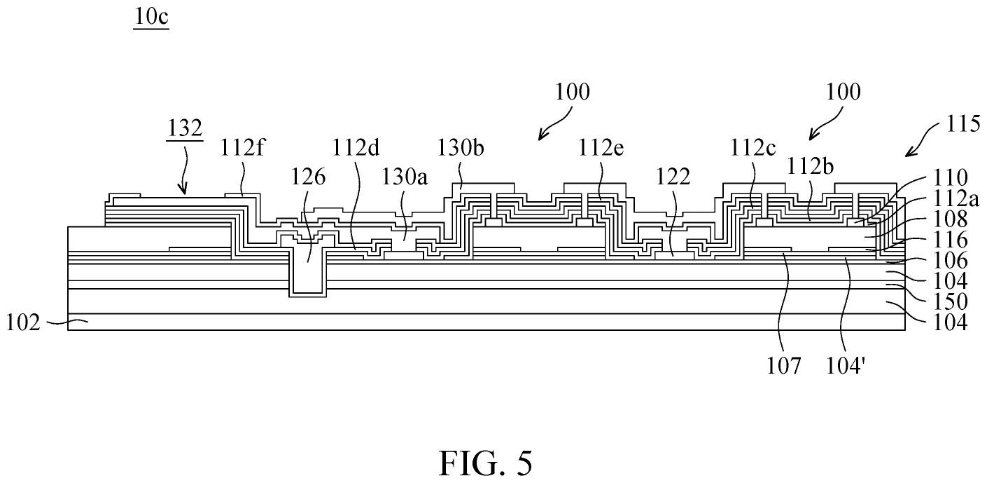

Many variations and/or modifications may be made to the embodiments of the disclosure. FIG. 5 is a cross-sectional representation of a VCSEL 10c in accordance with some embodiments. Some processes or devices are the same as, or similar to, those described in the embodiments above, and therefore the descriptions of these processes and devices are not repeated herein. The difference from the embodiments described above is that, as shown in FIG. 5 in accordance with some other embodiments, an isolation layer 150 is formed between the substrate 102 and the contact layer 106. In some embodiments, the isolation layer 150 is used to prevent or reduce current flowing from the active layer 107 to underlying substrate 102,

In some embodiments, the isolation layer 150 includes a reverse p/n junction, an oxide layer, an un-doped semiconductor layer, or a combination thereof. In some embodiments, the isolation layer 150 is inserted in the first mirror 104. Therefore, a current may not pass through the isolation layer 150 from the active layer 107 to the substrate 102 and/or the lower portion of the first mirror 104.

As shown in FIG. 5, in some embodiments, the isolation trench 124 is formed through the isolation layer 150, and the filler 126 is formed in the isolation trench 124. In some embodiments, the bottom surface of the filler 126 is lower than the isolation layer 150. Therefore, the isolation trench 124 may provide lateral isolation, and the isolation layer 150 may provide vertical isolation.

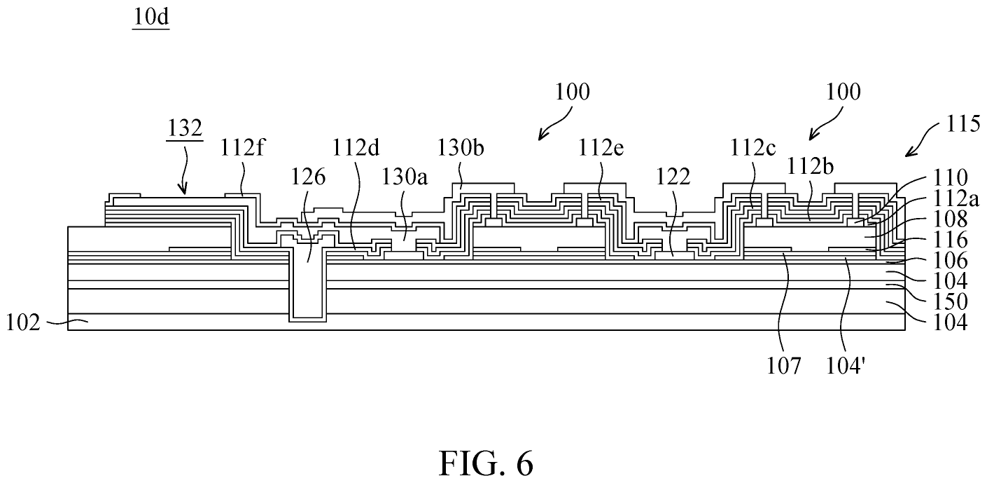

FIG. 6 is a cross-sectional representation of a VCSEL 10d in accordance with some embodiments. In some embodiments, the isolation trench 124 extends into the substrate 102. In some embodiments, the bottom surface of the filler 126 in the isolation trench 124 is between the top surface and the bottom surface of the substrate 102. In some embodiments, the bottom surface of the filler 126 is higher than the bottom surface of the substrate 102 and lower than the top surface of the substrate 102.

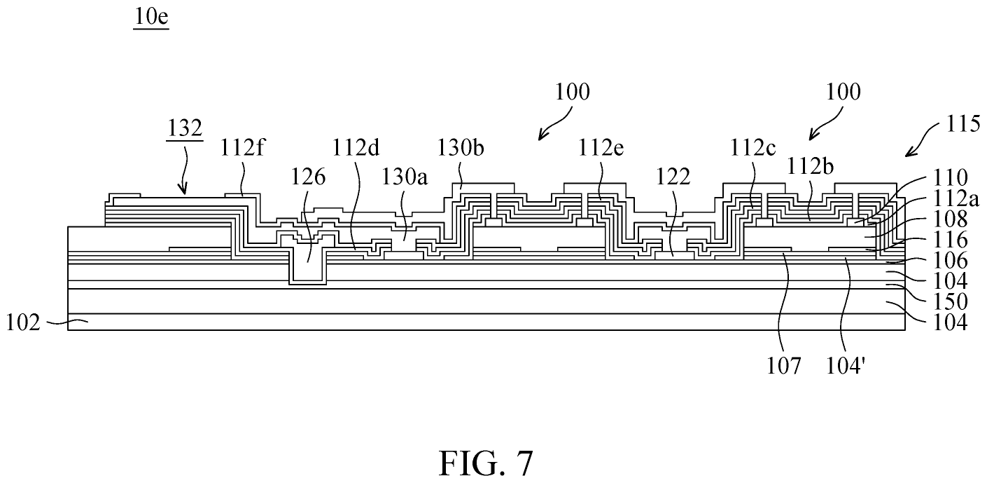

FIG. 7 is a cross-sectional representation of a VCSEL 10e in accordance with some embodiments. In some other embodiments, the isolation trench 124 extends into the isolation layer 150. In some embodiments, the bottom surface of the isolation trench 124 is between the top surface and the bottom surface of the isolation layer 150. In some embodiments, the bottom surface of the isolation trench 124 is higher than the bottom surface of the isolation layer 150 and lower than the top surface of the isolation layer 150.

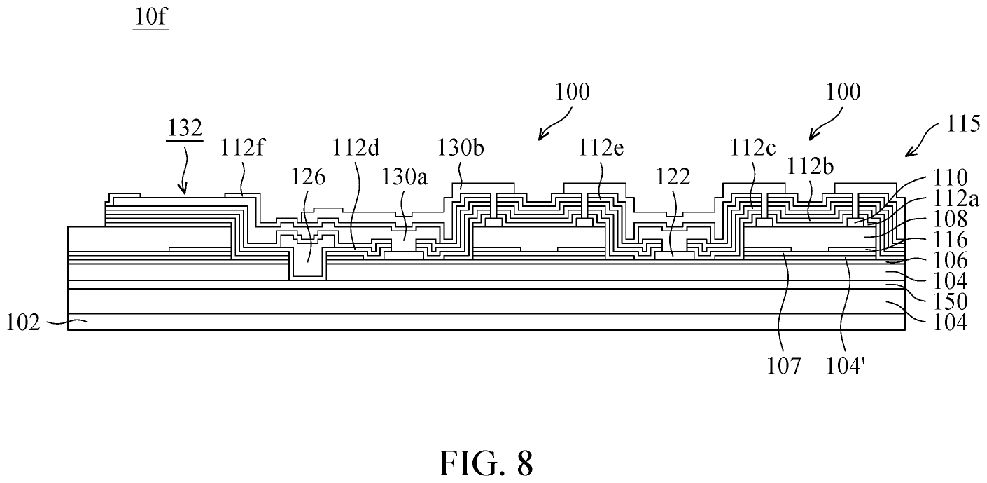

FIG. 8 is a cross-sectional representation of a VCSEL 10f in accordance with some embodiments. In some embodiments, the isolation trench 124 extends to the top surface of the isolation layer 150. In some embodiments, the isolation trench 124 stops at the top surface of the isolation layer 150. In some embodiments, the bottom surface of the isolation trench 124 is substantially level with the top surface of the isolation layer 150,

With a filler 126 formed in the isolation trench 124 between the VCSELs 100 of the VCSEL arrays 10d, 10e and 10f, thinner photoresist layer may be used in the patterning process (e.g., the patterning process for forming the via hole on the mesa 115), and thus the reliability and/or the yield of the VCSEL arrays 10d, 10e and 10f may be improved. In addition, the filler 126 in the isolation trench 124 may reduce the leakage current and thus improve the performance of the VCSEL arrays 10d, 10e and 10f. An isolation layer 150 may be formed in the first mirror 104 to provide vertical isolation, and leakage current may be reduced. The bottom surface of the filler 126 may be located between the top surface and the bottom surface of the substrate 102. The bottom surface of the filler 126 may be located between the top surface and the bottom surface of the isolation layer 150. The bottom surface of the filler 126 may be substantially level with the top surface or the bottom surface of the isolation layer 150.

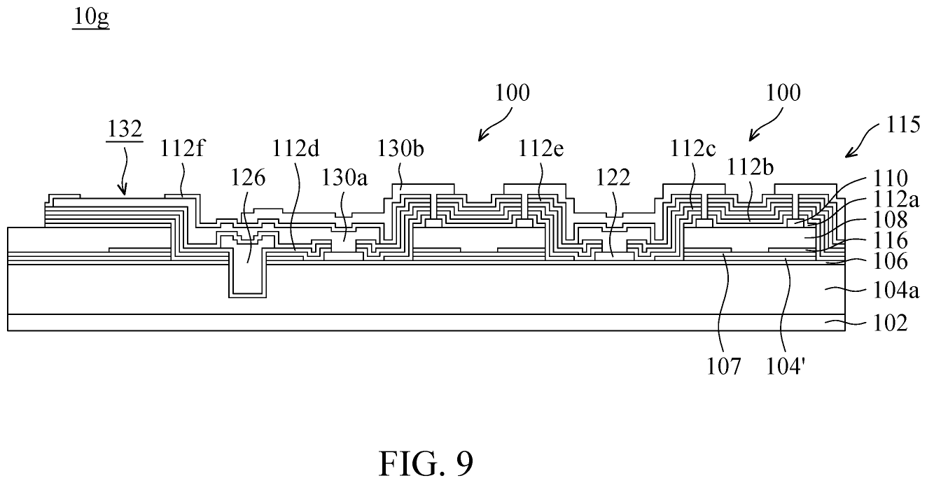

Many variations and/or modifications may be made to the embodiments of the disclosure. FIG. 9 is a cross-sectional representation of a modified VCSEL 10g in accordance with some embodiments. Some processes or devices are the same as, or similar to, those described in the embodiments above, and therefore the descriptions of these processes and devices are not repeated herein. The difference from the embodiments described above is that, as shown in FIG. 9 in accordance with some other embodiments, the mirror formed over the substrate 102 is an un-doped mirror 104a.

In some embodiments, the isolation trench 124 is formed through the un-doped mirror 104a. The un-doped mirror 104a may provide vertical isolation. In some embodiments, the bottom surface of the isolation trench 124 is higher than the bottom surface of the un-doped mirror 104a.

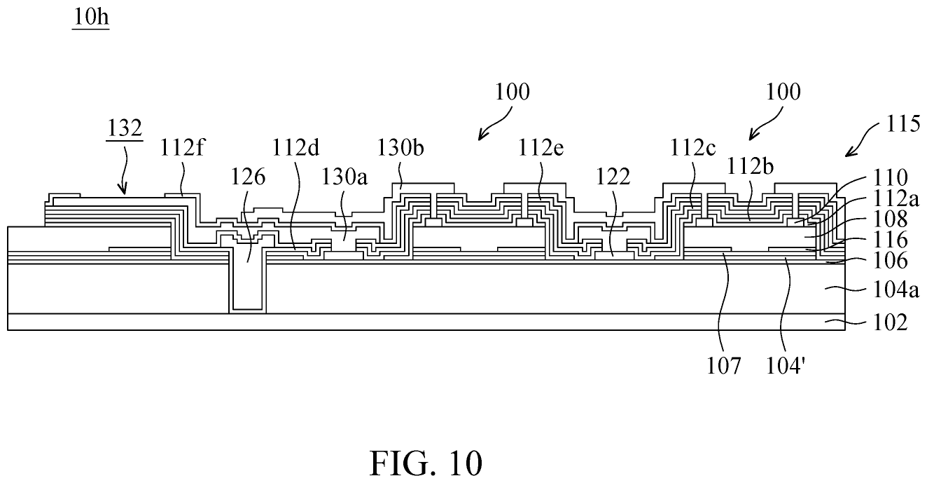

FIG. 10 is a cross-sectional representation of a VCSEL 10h in accordance with some embodiments. In some embodiments, the isolation trench 124 extends to the top surface of the substrate 102. In some embodiments, the bottom surface of the isolation trench 124 is substantially level with the top surface of the substrate 102.

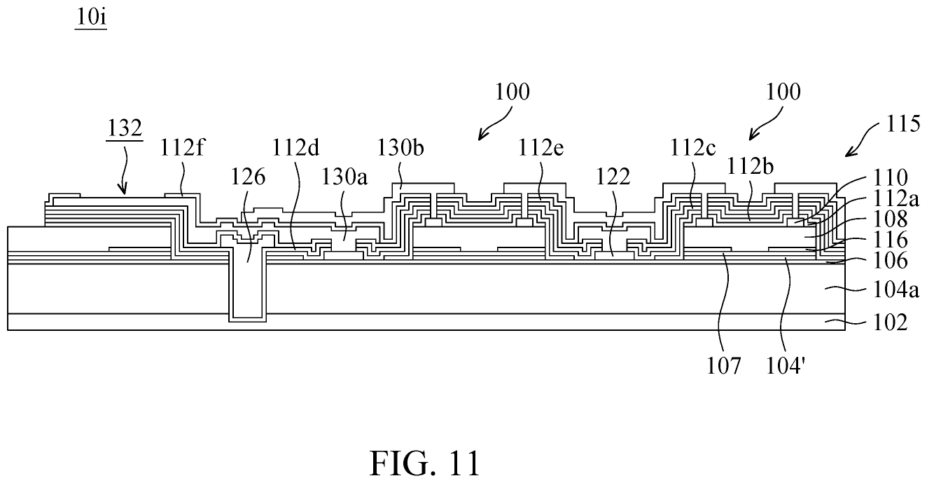

FIG. 11 is a cross-sectional representation of a VCSEL 10i in accordance with some embodiments. In some embodiments, the isolation trench 124 extends into the substrate 102. In some embodiments, the bottom surface of the filler 126 in the isolation trench 124 is between the top surface and the bottom surface of the substrate 102. In some embodiments, the bottom surface of the filler 126 is higher than the bottom surface of the substrate 102 and lower than the top surface of the substrate 102.

With a filler 126 formed in the isolation trench 124 between the VCSELs 100 of the VCSEL arrays 10g, 10h and 10i, thinner photoresist layer may be used in the patterning process (e.g., the patterning process for forming the via hole on the mesa 115), and thus the reliability and/or the yield of the VCSEL arrays 10g, 10h and 10i may be improved. In addition, the filler 126 in the isolation trench 124 may reduce the leakage current and thus improve the performance of the VCSEL arrays 10g, 10h and 10i. The un-doped mirror 104a formed over the substrate 102 may provide vertical isolation.

As mentioned above, in the present disclosure, a VCSEL array and a method of forming a VCSEL array is provided. An isolation trench filled with a filler is formed between the VCSELs. Thinner photoresist layer may be used in the patterning process (e.g., the patterning process for forming the via hole on the mesa), and thus the reliability and/or the yield of the VCSEL arrays may be improved. In addition, the filler in the isolation trench may reduce the leakage current and thus improve the performance of the VCSEL arrays.

It should be noted that although some of the benefits and effects are described in the embodiments above, not every embodiment needs to achieve all the benefits and effects.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A vertical-cavity surface-emitting laser (VCSEL) array, comprising:
a substrate;
an active layer formed between a lower mirror and an upper mirror;
a contact layer formed between the active layer and the substrate; and
an isolation trench extending through the contact layer between a first VCSEL and a second VCSEL of the VCSEL array,
wherein the isolation trench is filled with a filler.

2. The VCSEL array as claimed in claim 1, further comprising:
an isolation layer formed between the substrate and the contact layer.

3. The VCSEL array as claimed in claim 2, wherein the isolation layer is inserted into the lower mirror.

4. The VCSEL array as claimed in claim 2, wherein a bottom surface of the filler is lower than the isolation layer.

5. The VCSEL array as claimed in claim 1, wherein the isolation trench has a tapered sidewall.

6. The VCSEL array as claimed in claim 1, wherein the lower mirror is un-doped.

7. The VCSEL array as claimed in claim 1, wherein the filler is T-shaped in a cross-sectional view.

8. A vertical-cavity surface-emitting laser (VCSEL) array, comprising:
a lower mirror with an isolation layer formed over a substrate;
an active layer formed over the lower mirror;
an upper mirror formed over the active layer;
a contact layer formed over the isolation layer;
a first electrode formed over the upper mirror;
a second electrode formed over the contact layer;
an isolation trench surrounding a VCSEL of the VCSEL array; and
a dielectric layer formed over the second electrode,
wherein the isolation trench is filled with a filler made of a material different from that of the dielectric layer.

9. The VCSEL array as claimed in claim 8, further comprising:
an insulating layer lining the isolation trench.

10. The VCSEL array as claimed in claim 9, wherein the filler is electrically isolated from the contact layer by the insulating layer.

11. The VCSEL array as claimed in claim 8, wherein a top portion of the filler laterally extends out of the isolation trench.

12. The VCSEL array as claimed in claim 8, wherein the filler comprises metal, polymer, or a combination thereof.

13. The VCSEL array as claimed in claim 8, wherein the substrate is n-type doped or p-type doped.

14. The VCSEL array as claimed in claim 8, wherein the substrate is a semi-insulating substrate.

15. A method for forming a VCSEL array, comprising:
forming a lower mirror and a contact layer over a substrate;
forming an active layer over the lower mirror;
forming an upper mirror over the active layer;
patterning the upper mirror, the active layer, and the lower mirror to form a mesa over the contact layer;
forming a first electrode over the mesa;
forming a second electrode over the contact layer;
forming an isolation trench in the contact layer and the lower mirror; and
filling the isolation trench with a filler.

16. The method for forming a VCSEL array as claimed in claim 15, further comprising:
implanting the lower mirror to form an isolation layer.

17. The method for forming a VCSEL array as claimed in claim 15, wherein the active layer comprises multiple junction layers with a tunneling junction layer sandwiched between active junction layers.

18. The method for forming a VCSEL array as claimed in claim 17, wherein the active junction layers comprise an un-doped semiconductor layer sandwiched between a p-type doped semiconductor layer and an n-type doped semiconductor layer.

19. The method for forming a VCSEL array as claimed in claim 15, wherein the first electrode and the second electrode are formed on the same side of the substrate.

20. The method for forming a VCSEL array as claimed in claim 15, wherein the substrate is a n-type substrate.
